(19) United States
(12) Patent Application Publication
(10) Pub. No.: US 2023/0097408 A1
(43) Pub. Date: Mar. 30, 2023

(54) SEMICONDUCTOR DEVICE AND METHOD OF MANUFACTURING THE SAME

(71) Applicant: RENESAS ELECTRONICS CORPORATION, Tokyo (JP)

(72) Inventors: Nozomi ITO, Tokyo (JP); Kazuyoshi MAEKAWA, Tokyo (JP); Yuji TAKAHASHI, Tokyo (JP); Yasuaki TSUCHIYA, Tokyo (JP); Nobuhito SHIRAISHI, Tokyo (JP)

(21) Appl. No.: 17/489,145

(22) Filed: Sep. 29, 2021

(51) Int. Cl. H01L 49/02; H01L 23/522; H01C 7/00; H01C 17/12

(52) U.S. Cl. CPC H01L 28/24; H01L 23/5228; H01C 7/006; H01C 17/12

(57) ABSTRACT

A semiconductor device includes an insulating layer, a first conductive film, a second conductive film and a thin-film resistor. The insulating layer has a penetrating portion. The first conductive film is formed in the penetrating portion such that a recess is formed at an upper part of the penetration portion. The second conductive film is formed on an upper surface of the first conductive film and an inner surface of the penetrating portion. The thin-film resistor includes silicon and metal. The thin-film resistor is formed on the second conductive film and the insulating layer.

### BACKGROUND

A present embodiment relates to a semiconductor device and a method of manufacturing the semiconductor device, and, for example, to a semiconductor device including a thin-film resistor.

There is disclosed technique listed below. [Patent Document 1] Japanese Unexamined Patent Application Publication No. 2014-165458

As an analog semiconductor device, a semiconductor device including a thin-film resistor is known. The thin-film resistor can be arbitrarily cut. As a result, the characteristics of the semiconductor device can be adjusted.

The semiconductor device described in Patent Document 1, includes: an interlayer insulating film; a via formed in the interlayer insulating film such that the via penetrates the interlayer insulating film; a thin-film resistor formed on the interlayer insulating film such that the thin-film resistor is electrically connected with the via; an insulating film formed on the interlayer insulating film such that the insulating film covers the thin-film resistor; a wiring formed on the insulating film; and a dummy wiring formed on the insulating film. The dummy wiring, in plan view, is formed such that the dummy wiring includes the thin-film resistor. In the semiconductor device described in Patent Document 1, the thin-film resistor is protected by the dummy wiring.

### SUMMARY

In the semiconductor device described in Patent Document 1, for example, the via is formed by embedding a conductive film in a via hole formed in the interlayer insulating film, and then planarizing the conductive film by etching method or CMP method. At this instance, a gap (hereinafter also referred to as a “recess”) may be formed above the conductive film in the via hole. When the thin-film resistor is formed on the via and the interlayer insulating film in a state in which the recess is formed, the thin-film resistor may be thinned or cut off at a step part of the recess. As a result, it causes a decrease in the reliability of the semiconductor device.

A problem of the embodiment is to increase the reliability of the semiconductor device. Other problems and novel features will become apparent from the description of the specification and drawings.

An semiconductor device according to an embodiment includes: an insulating layer having a penetrating portion; a first conductive film formed in the penetrating portion such that a recess is formed at an upper part of the penetrating portion; a second conductive film formed on an upper surface of the first conductive film and an inner surface of the penetrating portion; and a thin-film resistor including silicon and metal and formed on the second conductive film and the insulating layer.

A method of manufacturing a semiconductor device according to an embodiment includes: forming a first conductive film in a penetrating portion formed in the insulating layer such that a recess is formed at an upper part of the penetrating portion; forming a second conductive film on an upper surface of the first conductive film and an inner surface of the penetrating portion; and forming a thin-film resistor on the second conductive film and the insulating layer.

According to the embodiment, it is possible to increase the reliability of the semiconductor device.

### BRIEF DESCRIPTION OF THE DRAWINGS

FIG. 1 is a plan view showing an exemplary configuration of a semiconductor device according to a first embodiment.

FIG. 2 is a cross-sectional view showing an exemplary configuration of the semiconductor device according to the first embodiment.

FIG. 3 is a cross-sectional view of a main part showing an exemplary step included in a method of manufacturing the semiconductor device according to the first embodiment.

FIG. 4 is a cross-sectional view of a main part showing an exemplary step included in the method of manufacturing the semiconductor device according to the first embodiment.

FIG. 5 is a cross-sectional view of a main part showing an exemplary step included in the method of manufacturing the semiconductor device according to the first embodiment.

FIG. 6 is a cross-sectional view of a main part showing an exemplary step included in the method of manufacturing the semiconductor device according to the first embodiment.

FIG. 7 is a cross-sectional view of a main part showing an exemplary step included in the method of manufacturing the semiconductor device according to the first embodiment.

FIG. 8 is a cross-sectional view of a main part showing an exemplary step included in the method of manufacturing the semiconductor device according to the first embodiment.

FIG. 9 is a cross-sectional view of a main part showing an exemplary step included in the method of manufacturing the semiconductor device according to the first embodiment.

FIG. 10 is a cross-sectional view of a main part showing an exemplary step included in the method of manufacturing the semiconductor device according to the first embodiment.

FIG. 11 is a cross-sectional view of a main part showing an exemplary step included in the method of manufacturing the semiconductor device according to the first embodiment.

FIG. 12 is a cross-sectional view of a main part showing an exemplary step included in the method of manufacturing the semiconductor device according to the first embodiment.

FIG. 13 is a cross-sectional view of a main part showing a step of forming a thin film resistor included in a method of manufacturing a semiconductor device for comparison.

FIG. 14 is a cross-sectional view of a main part showing a step of forming a thin film resistor included in the method of manufacturing the semiconductor device according to the first embodiment.

FIG. 15 is a cross-sectional view showing an exemplary configuration of a semiconductor device according to a first modification of the first embodiment.

FIG. 16 is a cross-sectional view showing an exemplary configuration of a semiconductor device according to a second modification of the first embodiment.

FIG. 17 is a cross-sectional view showing an exemplary configuration of a semiconductor device according to a third modification of the first embodiment.

FIG. 18 is a cross-sectional view of a main part showing an exemplary step included in a method of manufacturing the semiconductor device according to the third modification of the first embodiment.

FIG. 19 is a cross-sectional view showing an exemplary configuration of a semiconductor device according to a second embodiment.

FIG. 20 is a cross-sectional view of a main part showing an exemplary step included in a method of manufacturing the semiconductor device according to the second embodiment.

FIG. 21 is a cross-sectional view of a main part showing an exemplary step included in the method of manufacturing the semiconductor device according to the second embodiment.

FIG. 22 is a cross-sectional view of a main part showing an exemplary step included in the method of manufacturing the semiconductor device according to the second embodiment.

FIG. 23 is a cross-sectional view of a main part showing an exemplary step included in the method of manufacturing the semiconductor device according to the second embodiment.

FIG. 24 is a cross-sectional view of a main part showing an exemplary step included in the method of manufacturing the semiconductor device according to the second embodiment.

FIG. 25 is a cross-sectional view of a main part showing an exemplary step included in the method of manufacturing the semiconductor device according to the second embodiment.

FIG. 26 is a cross-sectional view of a main part showing an exemplary step included in the method of manufacturing the semiconductor device according to the second embodiment.

FIG. 27 is a cross-sectional view of a main part showing an exemplary step included in the method of manufacturing the semiconductor device according to the second embodiment.

FIG. 28 is a cross-sectional view of a main part showing an exemplary step included in the method of manufacturing the semiconductor device according to the second embodiment.

FIG. 29 is a cross-sectional view of a main part showing an exemplary step included in the method of manufacturing the semiconductor device according to the second embodiment.

FIG. 30 is a cross-sectional view of a main part showing an exemplary step included in the method of manufacturing the semiconductor device according to the second embodiment.

FIG. 31 is a cross-sectional view of a main part showing an exemplary step included in the method of manufacturing the semiconductor device according to the second embodiment.

### DETAILED DESCRIPTION

Hereinafter, a semiconductor device according to an embodiment will be described in detail with reference to the drawings. In the specification and the drawings, the same or corresponding components are denoted by the same reference numerals, and a repetitive description thereof is omitted. In the drawings, for convenience of description, the configuration may be omitted or simplified. From the viewpoint of visibility, even in a plan view, hatching may be attached. In addition, a cross-sectional view may be shown as an end view.

### First Embodiment

A semiconductor device SD1 according to a first embodiment, as a wiring WR1, including an aluminum wiring.

(Configuration of the Semiconductor Device)

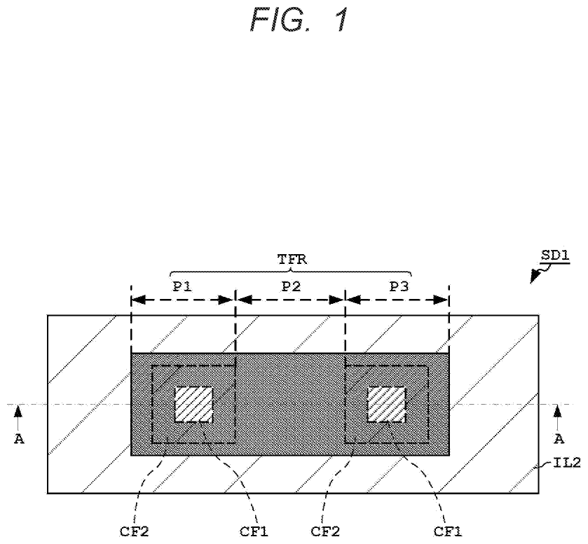

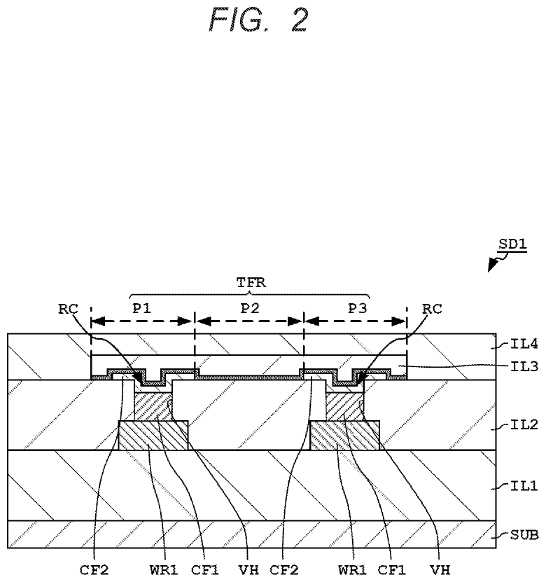

FIG. 1 is a plan view showing an exemplary configuration of a semiconductor device SD1 according to the first embodiment. FIG. 2 is a cross-sectional view showing an exemplary configuration of the semiconductor device SD1. FIG. 2 is the cross-sectional view taken along line A-A in FIG. 1.

The semiconductor device SD1 includes a semiconductor substrate SUB, a first insulating layer IL1, a wiring WR1, a second insulating layer IL2, a first conductive film CF1, a second conductive film CF2, a thin-film resistor TFR, a third insulating layer IL3 and a fourth insulating layer IL4. The first insulating layer IL1, the wiring WR1, the second insulating layer IL2, the first conductive film CF1, the second conductive film CF2, the thin-film resistor TFR, the third insulating layer IL3 and the fourth insulating layer IL4 constitute a multilayer wiring layer.

The semiconductor substrate SUB supports the multilayer wiring layer. Although not shown in particular, a semiconductor element is formed in a main surface of the semiconductor substrate SUB. The semiconductor element is, for example, a transistor. A material of the semiconductor substrate SUB is, for example, single crystal silicon.

The first insulating layer IL1 is formed on the semiconductor substrate SUB. The first insulating layer IL1 may be a single-layer film or a multi-layer film composed of a plurality of layers. A thickness of the first insulating layer IL1 is, for example, 1 μm or more and 3 μm or less. The material of the first insulating layer IL1 is, for example, silicon oxide.

The wiring WR1 is formed on an upper surface of the first insulating layer IL1. In the first embodiment, the wiring WR1 includes aluminum. In a thickness direction of the wiring WR1, the wiring WR1 is located between the semiconductor substrate SUB and the thin-film resistor TFR. The wiring WR1 is electrically connected with the thin-film resistor TFR through the first conductive film CF1 and the second conductive film CF2.

In the first embodiment, a pair of wirings WR1 is electrically connected with the thin-film resistor TFR through the first conductive film CF1 and the second conductive film CF2. One wiring WR1 is electrically connected with one end of the thin-film resistor TFR. Another wiring WR1 is electrically connected with another end of the thin-film resistor TFR.

The second insulating layer IL2 is formed on the upper surface of the first insulating layer IL1 such that the second insulating layer IL2 covers the wiring WR1. The second insulating layer IL2 has a via hole VH (a penetrating portion) formed such that the via hole VH reaches the wiring WR1. An example of a thickness and a material of the second insulating layer IL2 are the same as those of the first insulating layer IL1.

The first conductive film CF1 is formed in the via hole VH such that the first conductive film CF1 directly contacts with the wiring WR1. The first conductive film CF1 is formed at a lower part of the via hole VH such that a recess RC is formed at an upper part of the via hole VH. In the first embodiment, the first conductive film CF1 is a so-called via.

A depth of the recess RC is preferably small. In the present embodiment, since the semiconductor device SD1 includes the second conductive film CF2, the depth of the recess RC, for example, may be 4 times or more of a thickness of the thin-film resistor TFR, or may be 10 times or more of the thickness of the thin-film resistor TFR. The depth of the recess RC is, for example, 20 nm or more and 150 nm or less. The depth of the recess RC, in a thickness direction of the second insulating layer IL2, is a distance between the upper surface of the first conductive film CF1 and the upper surface of the second insulating layer IL2.

In the first embodiment, as shown in FIG. 2, a pair of first conductive films CF1 is electrically connected with the thin-film resistor TFR through a pair of second conductive films CF2. One first conductive film CF1 is electrically connected with one end of the thin-film resistor TFR. Another first conductive film CF1 is electrically connected with another end of the thin-film resistor TFR.

A width of the first conductive film CF1 is preferably greater than a height of the first conductive film CF1. Thus, a contact resistance between the first conductive film CF1 and the second conductive film CF2 can be reduced by increasing a contact area between the first conductive film CF1 and the second conductive film CF2. The width of the first conductive film CF1 is a length of the first conductive film CF1 in a direction along the main surface of the semiconductor substrate SUB. The height of the first conductive film CF1 is a length of the first conductive film CF1 in a direction along the thickness direction of the second insulating layer IL2.

A material of the first conductive film CF1 is not particularly limited. An example of the material of the first conductive film CF1 includes tungsten, titanium tungsten, copper, aluminum, cobalt, and rubidium.

The second conductive film CF2 is formed on at least the upper surface of the first conductive film CF1 and the inner surface of the via hole VH. In the first embodiment, the second conductive film CF2 is continuously formed on the upper surface of the first conductive film CF1, the inner surface of the via hole VH, and the upper surface of the second insulating layer IL2.

A thickness of the second conductive film CF2 is preferably greater than a thickness of the thin-film resistor TFR. Thus, due to a step part of the recess RC, it is possible to suppress reduction of coverage of the second conductive film CF2 on the inner surface of the via hole VH. The thickness of the second conductive film CF2 is preferably smaller than the depth of the recess RC. Thus, it is possible to suppress the thin-film resistor TFR is cut off due to the step part formed between the upper surface of the second insulating layer IL2 and the upper surface of the second conductive film CF2. The thickness of the second conductive film CF2 is, for example, 5 nm or more and 50 nm or less.

An example of a material for the second conductive film CF2 includes titanium nitride, tungsten, aluminum, cobalt, and rubidium. A thermal expansion coefficient of the material of the second conductive film CF2 is preferably smaller than a thermal expansion coefficient of the material of the first conductive film CF1. Thus, it is possible to reduce stress generated in accordance with the difference in the thermal expansion coefficient. Thus, it is possible to suppress breakage of the thin-film resistor TFR due to the stress. For example, when the material of the first conductive film CF1 is copper or aluminum, the material of the second conductive film CF2 is preferably titanium nitride or tungsten.

In the first embodiment, a pair of second conductive films CF2 is electrically connected with the thin-film resistor TFR. One second conductive film CF2 is electrically connected with one end of the thin-film resistor TFR. Another second conductive film CF2 is electrically connected with another end of the thin-film resistor TFR.

The thin-film resistor TFR is continuously formed on the second conductive film CF2 and the second insulating layer IL2. The thin-film resistor TFR directly contacts with a part or an entire of the upper surface of the second conductive film CF2. From the viewpoint of reducing the contact resistance, the thin-film resistor TFR is preferably directly contacts with the entire of the upper surface of the second conductive film CF2. The thin-film resistor TFR covers the pair of second conductive films CF2. That is, in plan view, the thin-film resistor TFR overlaps with the entire of the second conductive film CF2.

As shown in FIGS. 1 and 2, the thin-film resistor TFR includes a first part P1, a second part P2 and a third part P3. The first part P1, when viewed in plan, in an extending direction of the thin-film resistor TFR, is one end of the thin-film resistor TFR. The third part P3, when viewed in plan, in the extending direction of the thin-film resistor TFR, is another end of the thin-film resistor TFR. The first part P1 and the third part P3 are formed on the second conductive film CF2 and the second insulating layer IL2 such that the first part P1 and the third part P3 directly contact with the second conductive film CF2. When viewed in plan, in the extending direction of the thin-film resistor TFR, the second part P2 is located between the first part P1 and the third part P3. When viewed in plan, in the extending direction of the thin-film resistor TFR, the second part P2 is located between the pair of second conductive films CF2. The second part P2 is formed on the second insulating layer IL2 without the second part P2 directly contacting with the second conductive film CF2.

The thin-film resistor TFR includes silicon and metal. An example of the metal includes chromium and carbon. Specifically, the thin-film resistor TFR is, for example, silicon chromium or silicon chromium containing carbon.

The thickness of the thin-film resistor TFR can be appropriately adjusted according to a desired resistance value. From the viewpoint of increasing a resistance value of the thin-film resistor TFR, the thickness of the thin-film resistor TFR is preferably 5 nm or less.

The third insulating layer IL3 is formed on the thin-film resistor TFR. The third insulating layer IL3 is a protective film (mask) when patterning the thin-film resistor TFR. As shown in FIG. 2, a side surface of the third insulating layer IL3 is continuous with an end side surface of the thin-film resistor TFR. A thickness and a material of the third insulating layer IL3 are not particularly limited as long as the above function can be obtained. The thickness of the third insulating layer IL3 is, for example, 20 nm or more and 200 nm or less. An example of the material of the third insulating layer IL3 is the same as the example of the material of the first insulating layer IL1.

The fourth insulating layer IL4 is formed on the second insulating layer IL2 such that the fourth insulating layer IL4 covers the thin-film resistor TFR and the third semiconductor layer IL3. An example of a thickness and a material of the fourth insulating layer IL4 is the same as those of the first insulating layer IL1.

(Method of Manufacturing a Semiconductor Device)

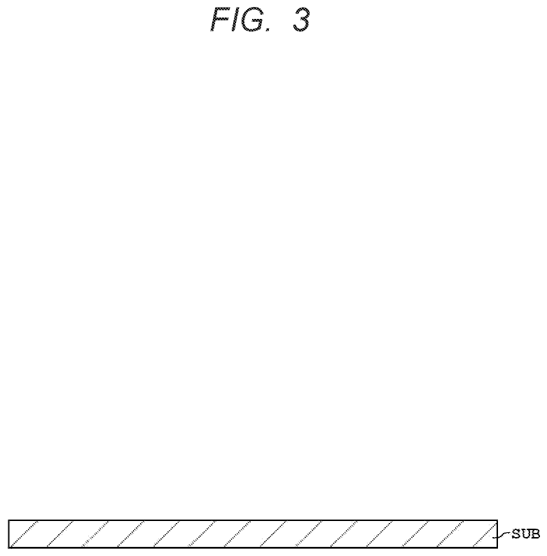

Next, an example of a method of manufacturing the semiconductor device SD1 according to the first embodiment will be described. FIGS. 3 to 12 are cross-sectional views of main parts showing exemplary steps included in the method of manufacturing the semiconductor device SD1.

For example, a method of manufacturing a semiconductor device SD1 according to the first embodiment includes: (1) preparing the semiconductor substrate SUB, (2) forming the first insulating layer IL1, (3) forming the wiring WR1, (4) forming the second insulating layer IL2, (5) forming the first conductive film CF1, (6) forming the second conductive film CF2, (7) forming the thin-film resistor TFR and the third insulating layer IL3, and (8) forming the fourth insulating layer IL4.

(1) Preparation the Semiconductor Substrate SUB

As shown in FIG. 3, the semiconductor substrate SUB is prepared. For example, the semiconductor substrate SUB can be purchased as off-the-shelf products. The semiconductor element may be formed on the semiconductor substrate SUB.

(2) Forming the First Insulating Layer IL1

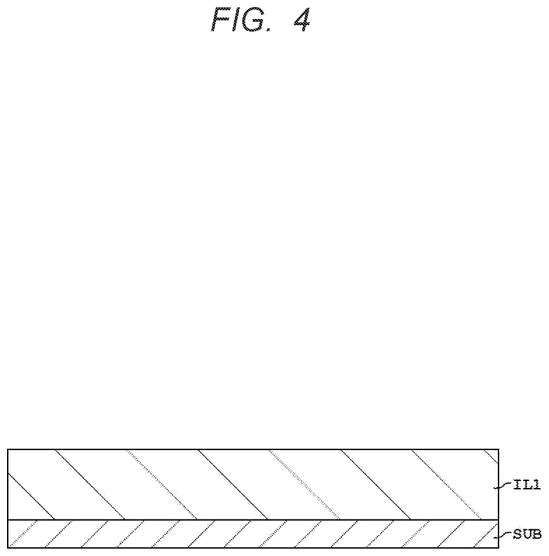

Subsequently, as shown in FIG. 4, the first insulating layer IL1 is formed on the semiconductor substrate SUB. The first insulating layer IL1 is formed by, for example, a CVD method.

(3) Forming the Wiring WR1

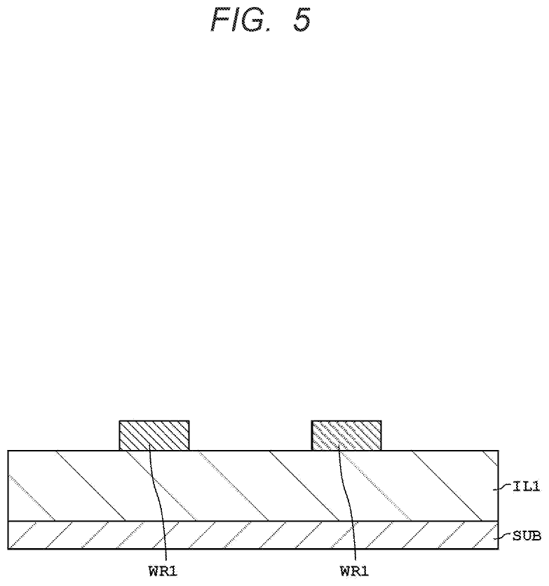

Subsequently, as shown in FIG. 5, the wiring WR1 is formed on the first insulating layer IL1. The wiring WR1 is formed by, for example, forming a conductive film on the first insulating layer IL1 by a sputtering method, and subsequently forming the conductive film to a desired shape by a patterning method.

(4) Forming the Second Insulating Layer IL2

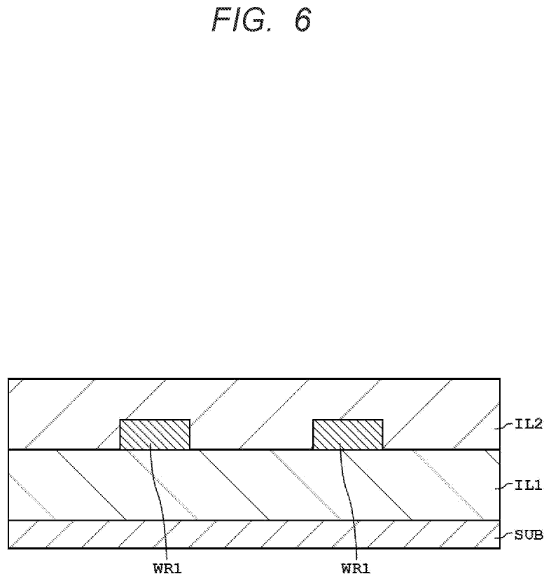

Subsequently, as shown in FIG. 6, the second insulating layer IL2 is formed on the first insulating layer IL1 so as to cover the wiring WR1. The second insulating layer IL2 is formed by, for example, a CVD method.

(5) Forming the First Conductive Film CF1

Subsequently, the first conductive film CF1 is formed in the via hole VH so as to form the recess RC at the upper part of the via hole VH formed in the second insulating layer IL2. Specifically, the forming the first conductive film CF1 includes: (5-1) forming the via hole VH; (5-2) forming a conductive film CF1′; and (5-3) performing CMP.

(5-1) Forming the via hole VH

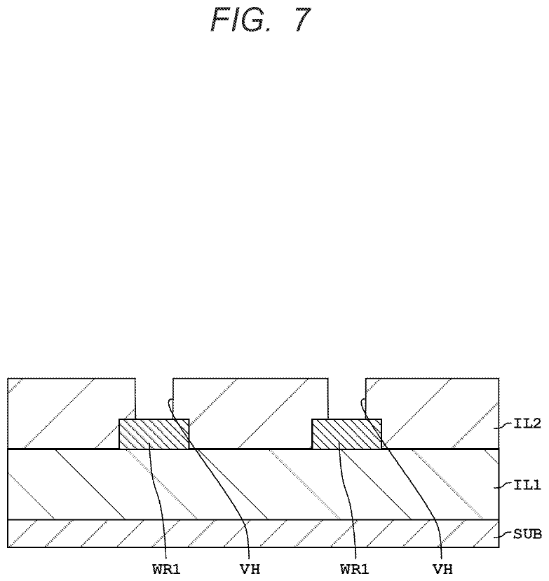

First, as shown in FIG. 7, the via hole VH is formed in the second insulating layer IL2 so as to reach the wiring WR in the thickness direction of the second insulating layer IL2. The via hole VH is formed by, for example, an etching method.

(5-2) Forming the Conductive Film CF1′

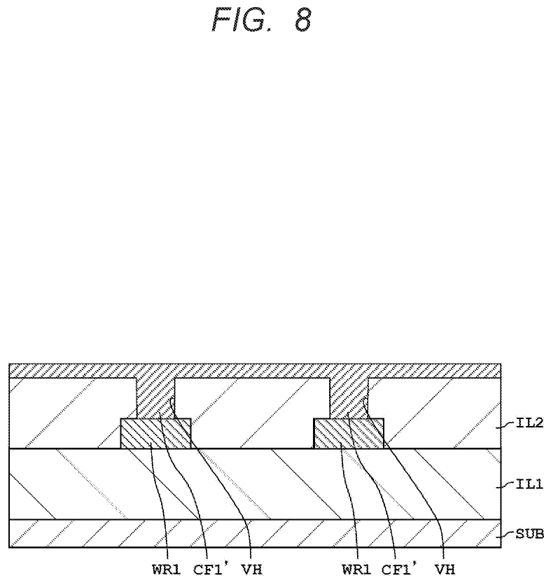

Subsequently, as shown in FIG. 8, the conductive film CF1′ is formed in the via hole VH. At this instance, the conductive film CF1′ may also be formed on the second insulating layer IL2, or may be formed only in the via hole VH. In the first embodiment, the conductive film CF1′ is also formed on the second insulating layer IL2. A method of forming the first conductive film CF1′ is, for example, a sputtering method.

(5-3) Performing CMP

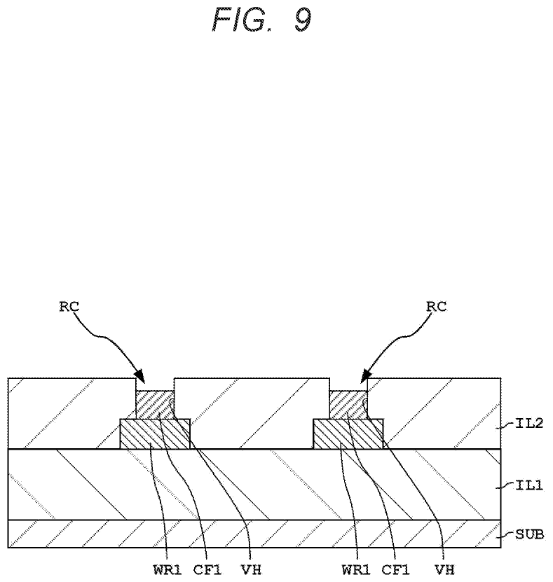

Subsequently, as shown in FIG. 9, a part of the conductive film CF1′, formed outside the via holes VH, is removed. A method of removing the part of the conductive film CF1′ is, for example, a CMP method. At this instance, the recess RC is formed in a part (an upper part) of an inside of the via hole VH, located above the conductive film CF1′. The recess RC is formed at the upper part of the via hole VH.

(6) Forming the Second Conductive Film CF2

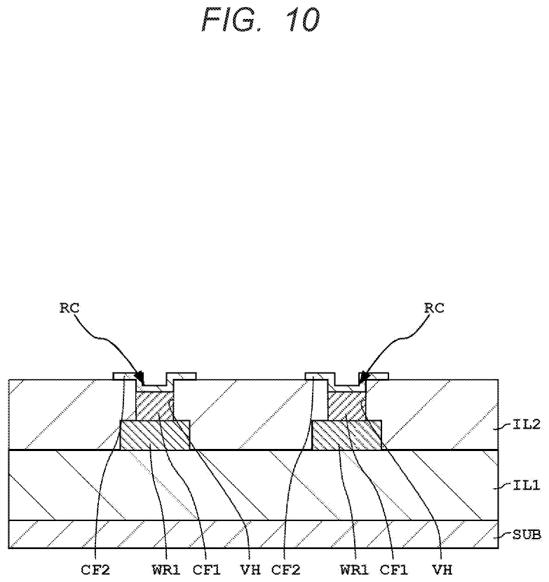

Subsequently, as shown in FIG. 10, the second conductive film CF2 is formed on at least the upper surface of the first conductive film CF1 and the inner surface of the via hole VH. In the first embodiment, the second conductive film CF2 is formed on the upper surface of the first conductive film CF1, the inner surface of the via hole VH, and the upper surface of the second insulating layer IL2. The second conductive film CF2, for example, is formed by forming a conductive film by a sputtering method and subsequently patterning the conductive film to a desired shape. A method of patterning the conductive film is, for example, an etching method.

(7) Forming the Thin-Film Resistor TFR and the Third Insulating Layer IL3

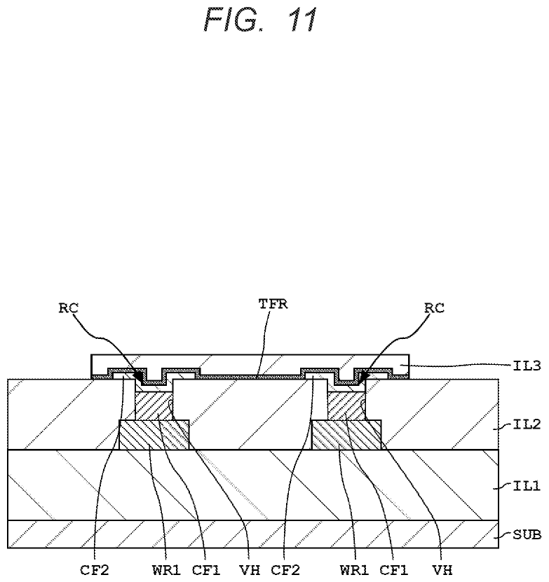

Subsequently, as shown in FIG. 11, the thin-film resistor TFR and the third insulating layer IL3 are formed. Specifically, at first, the thin film resistor TFR is formed on the upper surface of the second conductive film CF2 and the upper surface of the second insulating layer IL2. Subsequently, the third insulating layer IL3 is formed on the thin-film resistor TFR. The third insulating layer IL3 is then used as an etching mask to pattern the thin-film resistor TFR to the desired shapes. A method of forming the thin-film resistor TFR is, for example, a sputtering method. A method of patterning the thin-film resistor TFR is, for example, an etching method. The third insulating layer IL3 is formed by, for example, a CVD method.

(8) Forming the Fourth Insulating Layer IL4

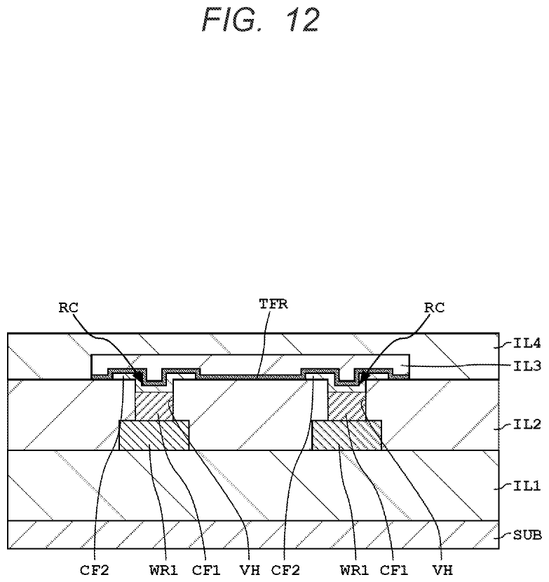

Subsequently, as shown in FIG. 12, the fourth insulating layer IL4 is formed on the second insulating layer IL2 so as to cover the third insulating layer IL3. The fourth insulating layer IL4 is formed by, for example, a CVD method.

The semiconductor device SD1 according to the first embodiment can be manufactured by the manufacturing method.

(Interaction of the Second Conductive Film CF2)

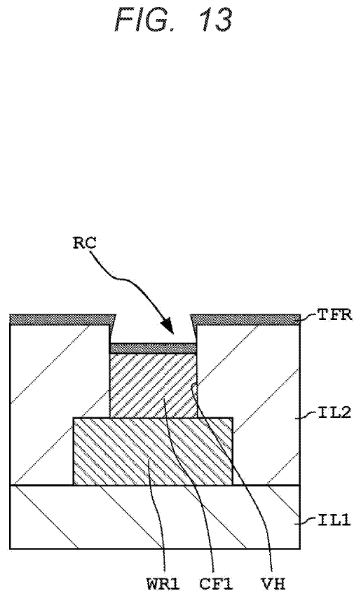

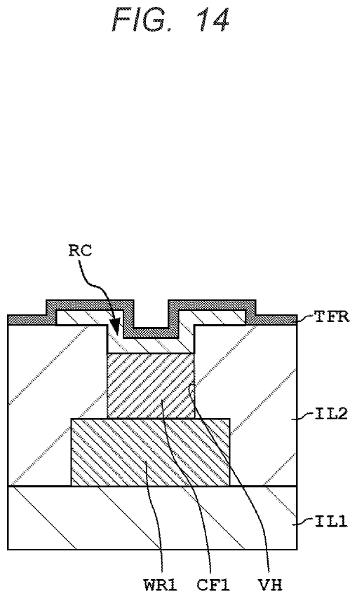

Next, the interaction of the second conductive film CF2 in the semiconductor device SD1 will be described. For comparison, a semiconductor device having no second conductive film CF2 (hereinafter also referred to as a “semiconductor device for comparison”) will also be described. FIG. 13 is a cross-sectional view of a main part showing a step of forming a thin film resistor TFR included in a method of manufacturing a semiconductor device for comparison. FIG. 14 is a cross-sectional view of a main part showing a step of forming the thin-film resistor TFR included in the manufacturing the semiconductor device SD1 according to the first embodiment.

As shown in FIG. 13, in the step of forming the thin-film resistor TFR in the semiconductor device for comparison, due to a step part of the recess RC, a part of the thin-film resistor TFR may be broken. Due to a difference between a thermal expansion coefficient of a material of the second insulating layer IL2 and a thermal expansion coefficient of a material of the first conductive film CF1, the stress is applied to the thin film resistor TFR in a vicinity of the first conductive film CF1. Therefore, among the thin-film resistor TFR, a part located in the vicinity of the first conductive film CF1 is easily broken. Thus, a electric connection between the thin-film resistor TFR and the first conductive film CF1 becomes unstable. As a result, a reliability of the semiconductor device is reduced.

On the other hand, the semiconductor device SD1 according to the first embodiment includes the second conductive film CF2. Therefore, as shown in FIG. 14, in the step of forming the thin-film resistor TFR in the semiconductor device SD1, the thin-film resistor TFR is formed on the second conductive film CF2 formed, in advance, in the recess RC. Therefore, even if a part of the thin-film resistor TFR is broken, the thin-film resistor TFR and the first conductive film CF1 can be stably electrically connected with each other through the second conductive film CF2. Further, when the difference between the thermal expansion coefficient of the material of the second insulating layer IL2 and the thermal expansion coefficient of the material of the second conductive film CF2 is smaller than the difference between the thermal expansion coefficient of the material of the second insulating layer IL2 and the thermal expansion coefficient of the material of the first conductive film CF1, it is also possible to reduce the stress applied to the thin-film resistor TFR. Thus, in the first embodiment, breakage of the thin-film resistor TFR is further suppressed. Consequently, it is possible to increase the reliability of the semiconductor device SD1.

### Effect

In the semiconductor device SD1 according to the first embodiment, the thin-film resistor TFR is formed on the first conductive film CF1 through the second conductive film CF2. Thus, as described above, the thin-film resistor TFR is stably electrically connected with the first conductive film CF1. Consequently, it is possible to increase the reliability of the semiconductor device SD1.

[First Modification]

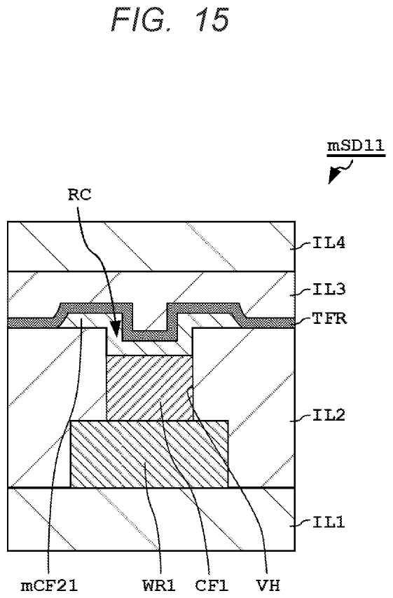

FIG. 15 is a partially enlarged plan view showing an exemplary configuration of a main part of a semiconductor device mSD11 according to a first modification of the first embodiment.

The semiconductor device mSD11 includes a second conductive film mCF21. An end side surface of the second conductive film mCF21 is an inclined surface which is inclined with respect to the upper surface of the second insulating layer IL2. The end side surface of the second conductive film mCF21, in a plan view, is an outer edge of the second conductive film mCF21. A thickness of the second conductive film mCF21 is smaller as it moves away from the recess RC in a direction along the upper surface of the second insulating layer IL2. The end side surface can be formed by performing isotropic etching with respect to the outer edge of the second conductive film mCF21.

As described above, in the first modification, the end side surface of the second conductive film mCF21 is inclined with respect to the upper surface of the second insulating layer IL2. Thus, the end side surface of the second conductive film mCF21, as compared with the case perpendicular to the upper surface of the second insulating layer IL2, a coverage of the thin-film resistor TFR formed on the end side surface of the second conductive film mCF21 is increased. Electrical contacts between the thin-film resistor TFRs and the second conductive film mCF21 become better. Consequently, in the first modification, it is possible to further enhance the reliability of the semiconductor device mSD11.

[Second Modification]

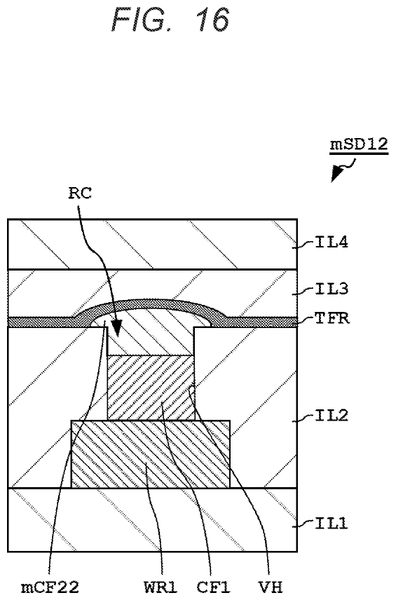

FIG. 16 is a partially enlarged plan view showing an exemplary configuration of a main part of a semiconductor device mSD12 according to a second modification of the first embodiment.

The semiconductor device mSD12 includes a second conductive film mCF22. A material of the second conductive film mCF22 is the same as the material of the first conductive film CF1. The second conductive film mCF22 is selectively formed on the first conductive film CF1 by the CVD method. In other words, the second conductive film mCF22, on the upper surface of the second insulating layer IL2, is formed only in the vicinity of the recess RC. As a result, the patterning step of the second conductive film mCF22 can be reduced. That is, if the patterning step of the second conductive film mCF22 can be omitted, the second conductive film mCF22 may be formed on the upper surface of the second insulating layer IL2.

The second conductive film mCF22 has a central part and a peripheral part. The center part of the second conductive film mCF22 overlaps the first conductive film CF1 in a plan view. The peripheral part of the second conductive film mCF22 is located on the upper surface of the second insulating layer IL2 without overlapping with the first conductive film CF1 in plan view. A thickness of the central part of the second conductive film mCF22 is greater than a thickness of the peripheral part of the second conductive film mCF22. The thickness of the second conductive film mCF22 is greater than a depth of the recess RC. Thus, the second conductive film mCF22 is formed such that the upper surface of the second conductive film mCF22 is located outside the recess RC. An entirety of the upper surface of the second conductive film mCF22 is preferably located outside the recess RC. In the thickness direction of the second insulating layer IL2, a distance between the upper surface of the second conductive film mCF22 and the upper surface of the first conductive film CF1 is greater than a distance between the upper surface of the second insulating layer IL2 and the upper surface of the first conductive film CF1. Also in the second modification, the end side surface of the second conductive film mCF22 is inclined with respect to the upper surface of the second insulating layer IL2. This increases a coverage of the thin-film resistor TFR formed on the second conductive film mCF22. Electrical contacts between the thin-film resistor TFR and the second conductive film mCF22 become better. Consequently, in the second modification, it is possible to further enhance the reliability of the semiconductor device mSD12.

[Third Modification]

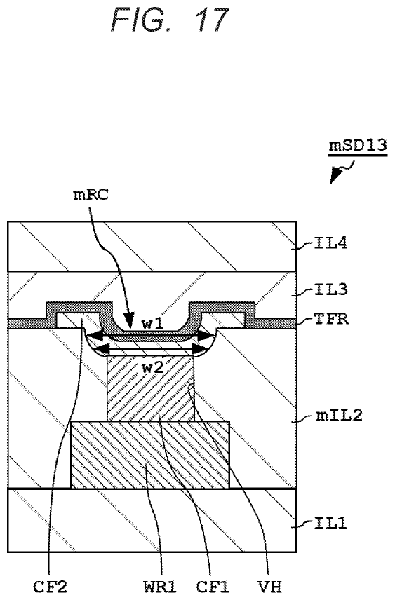

FIG. 17 is a partially enlarged plan view showing an exemplary configuration of a main part of a semiconductor device mSD13 according to a third modification of the first embodiment.

The semiconductor device mSD13 includes a second insulating layer mIL2 in which a recess mRC is formed. A size (a first width w1) of an upper part of the recess mRC is greater than a size (a second width w2) of a lower part of the recess mRC. Thus, as compared with a case where an inner surface of the recess mRC is perpendicular to the upper surface of the second insulating layer mIL2, a coverage of the second conductive film CF2 and the thin-film resistor TFR which are formed on the inner surface of the recess mRC is enhanced. Consequently, even in the third modification, it is possible to further enhance the reliability of the semiconductor device mSD13. From the viewpoint of further enhancing the coverage of the second conductive film CF2 and the thin-film resistor TFR, it is preferable that the inner surface of the recess mRC is a curved surface or an inclined surface with respect to the upper surface of the second insulating layer mIL2.

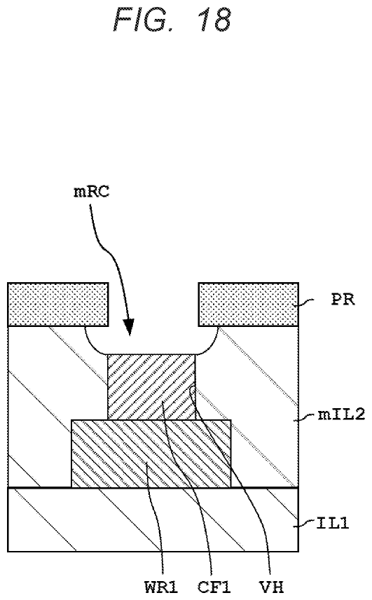

FIG. 18 is a cross-sectional view of a main part showing an exemplary step included in a method of the manufacturing the semiconductor device SDm13. A step of processing the recess mRC shown in FIG. 18 is performed after a step of forming the first conductive film CF1 (see FIG. 9). A method of processing the recess mRC, for example, is performed by an isotropic etching method using a photoresist mask PR. The isotropic etching method may be a dry etching method or a wet etching method.

In the third modification, for the recess mRC, isotropic etching is performed. As a result, the size (the first width w1) of the upper part of the recess mRC becomes greater than the size (the second width w2) of the lower part of the recess mRC. Consequently, it is possible to further enhance the reliability of the semiconductor device mSD13.

### Second Embodiment

A semiconductor device SD2 according to a second embodiment, as a wiring WR2, in that the semiconductor device SD2 includes a copper wiring, differs mainly from the semiconductor device SD1 according to the first embodiment. The first conductive film CF1 and the wiring WR1 according to the first embodiment correspond to the wiring WR2 according to the second embodiment. Hereinafter, the same components as those of the semiconductor device SD1 according to the first embodiment are denoted by the same reference numerals, and descriptions thereof are omitted.

(Configuration of the Semiconductor Device)

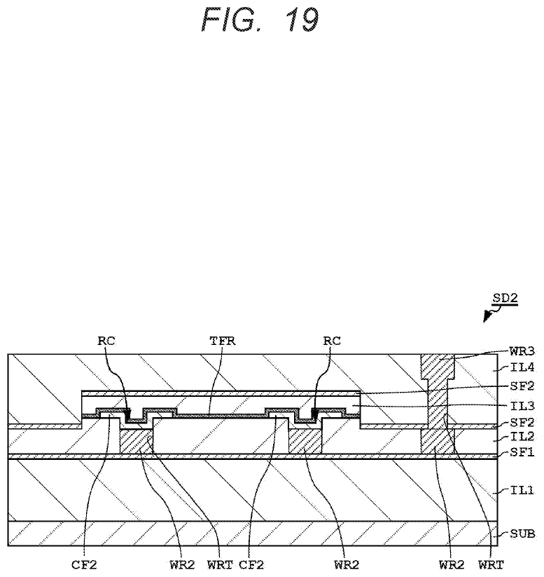

FIG. 19 is a cross-sectional view showing an exemplary configuration of a semiconductor device SD2 according to the second embodiment.

The semiconductor device SD2 includes a semiconductor substrate SUB, a first insulating layer IL1, a first stopper film SF1, a second insulating layer IL2, a wiring WR2, a second conductive film CF2, a thin-film resistor TFR, a third insulating layer IL3, a second stopper film SF2, a fourth insulating layer IL4 and a wiring WR3. The first insulating layer IL1, the first stopper film SF1, the wiring WR2, the second insulating layer IL2, the second conductive film CF2, the thin-film resistor TFR, the third insulating layer IL3, the second stopper film SF2, the fourth insulating layer IL4 and the wiring WR3 constitute a multilayer wiring layer.

The first stopper film SF1 is formed on the first insulating layer IL1. The first stopper film SF1, in a step of forming a wiring trench WRT of the second insulating layer IL2, functions as an etching stopper film. A thickness and a material of the first stopper film SF1 are not particularly limited as long as the above function can be obtained. The thickness of the first stopper film SF1 is smaller than the thickness of the second insulating layer IL2. The thickness of the first stopper film SF1 is, for example, 20 nm or more and 200 nm or less. The material of the first stopper film SF1 differs from the material of the second insulating layer IL2. The material of the first stopper film SF1 includes, for example, at least one composed of a group consisting of carbon, oxygen and nitrogen, and silicon. Examples of materials of the first stopper film SF1 include silicon carbide, silicon nitride and silicon carbonitride.

The second insulating layer IL2 is formed on the upper surface of the first stopper film SF1. The second insulating layer IL2 has a wiring trench WRT (penetrating portion) formed such that the wiring trench reaches the first stopper film SF1. Examples of the thickness and materials of the second insulating layer IL2 are the same as those of the first insulating layer IL1.

The wiring WR2 is formed in the wiring trench WRT of the second insulating layer IL2 such that the wiring WR2 reaches the upper surface of the first stopper film SF1. In the thickness direction of the wiring WR2, the wiring WR2 is located between the semiconductor substrate SUB and the thin-film resistor TFR. The wiring WR2 is electrically connected with the thin-film resistor TFR through the second conductive film CF2.

In the second embodiment, a pair of wirings WR2 is electrically connected with the thin-film resistor TFR through the second conductive film CF2. One of the wirings WR2 is electrically connected with one end of the thin-film resistor TFR. Another wiring WR2 is electrically connected with another end of the thin-film resistor TFR.

The wiring WR2 is formed in a lower part of the wiring trench WRT such that the recess RC is formed at the upper part of the wiring trench WRT. In the second embodiment, the materials of the wiring WR2 include, for example, copper.

The second conductive film CF2 is at least formed on the upper surface of the wiring WR2 and the inner surface of the wiring trench WRT. In the second embodiment, the second conductive film CF2, the upper surface of the wiring WR2, and the inner surface of the wiring trench WRR, is continuously formed on the upper surface of the second insulating layer IL2.

The second stopper film SF2 is formed on the third insulating layer IL3. The second stopper film SF2, in a step of forming the wiring trench WRT of the third insulating layer IL3, functions as an etching stopper film. Example of thickness and material of the second stopper film SF2 is similar to the first stopper film SF1.

The fourth insulating layer IL4 is formed on the second stopper film SF2. The fourth insulating layer IL4 has the wiring trench WRT formed such that the wiring trench WRT reaches the second stopper film SF2 (penetrating portion). Examples of the thickness and materials of the fourth insulating layer IL4 are the same as those of the first insulating layer IL1.

The wiring WR3 is formed in the wiring trench WRT of the fourth insulating layer IL4 such that the wiring WR3 penetrates the second stopper film SF2. The wiring WR3 is an upper-layer wiring electrically connected with the wiring WR2. The wiring WR3 may be a so-called single damascene wiring or may be a dual damascene wiring.

(Method of Manufacturing a Semiconductor Device)

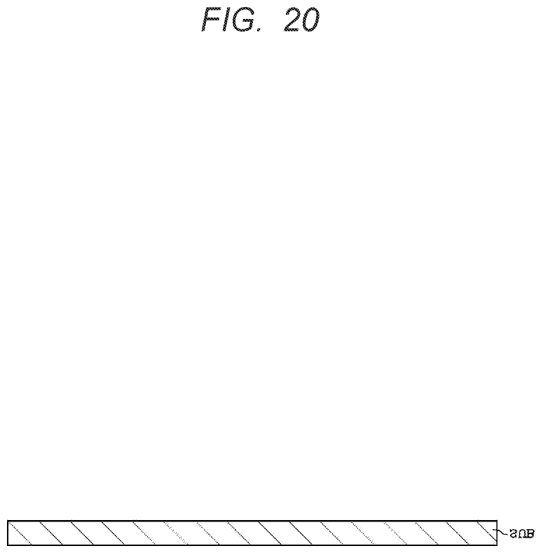

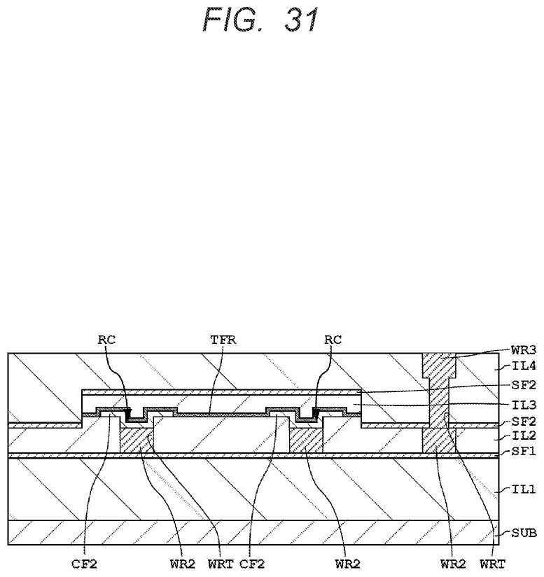

Next, exemplary method of manufacturing the semiconductor device SD2 according to the second embodiment will be described. FIGS. 20 to 31 are cross-sectional views of main parts showing exemplary steps included in the method of manufacturing the semiconductor device SD2.

For example, the method of manufacturing the semiconductor device SD2 according to the second embodiment includes: (1) preparing the semiconductor substrate SUB, (2) forming step of the first insulating layer IL1, (3) a forming the first stopper film SF1, (4) forming the second insulating layer IL2, (5) forming the wiring WR2, (6) forming the second conductive film CF2, (7) forming the thin-film resistor TFR and the third insulating layer IL3, (8) forming the second stopper film SF2, (9) forming the fourth insulating layer IL4, and (10) forming the wiring WR3.

(1) Preparing the Semiconductor Substrate SUB

As shown in FIG. 20, the semiconductor substrate SUB is prepared. For example, the semiconductor substrate SUB can be purchased as off-the-shelf products. The semiconductor element may be formed in the semiconductor substrate SUB.

(2) Forming the First Insulating Layer IL1

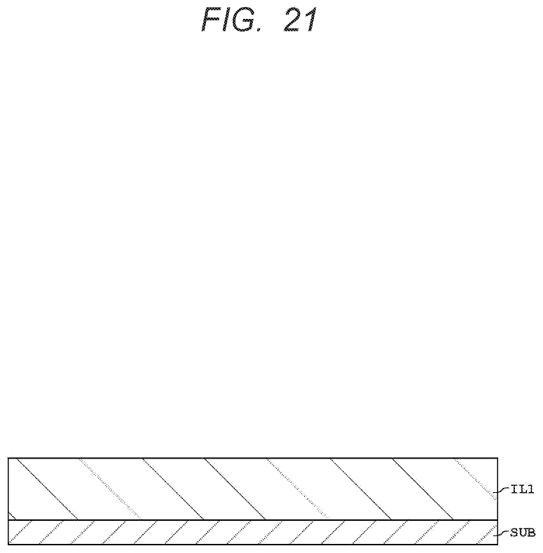

Subsequently, as shown in FIG. 21, the first insulating layer IL1 is formed on the semiconductor substrate SUB. The first insulating layer IL1 is formed by, for example, a CVD method.

(3) Forming the First Stopper Film SF1

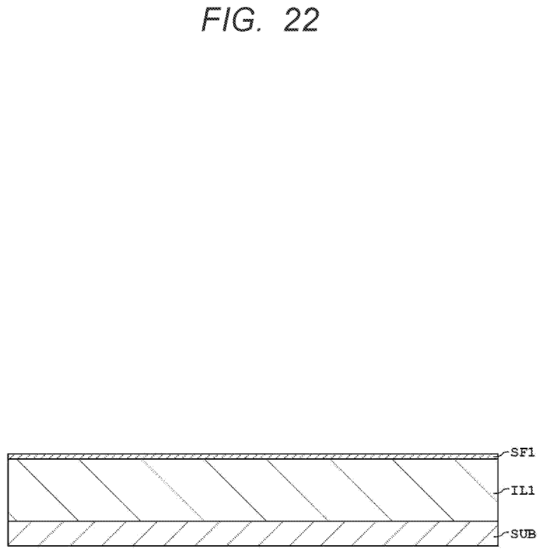

Subsequently, as shown in FIG. 22, the first stopper film SF1 is formed on the first insulating layer IL1. The first stopper film SF1 is formed by, for example, a sputtering method.

(4) Forming the Second Insulating Layer IL2

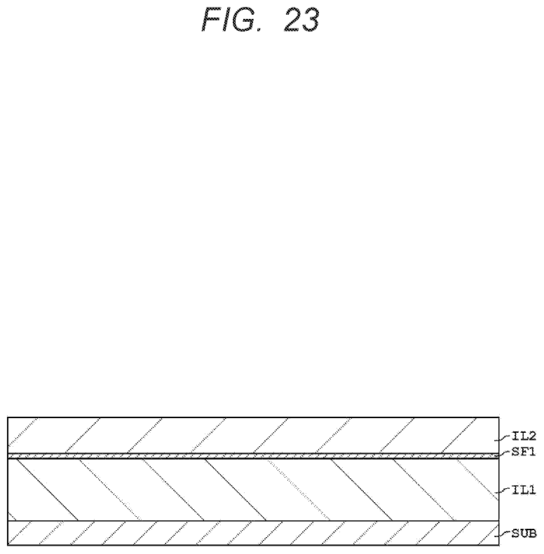

Subsequently, as shown in FIG. 23, the second insulating layer IL2 is formed on the first stopper film SF1. The second insulating layer IL2 is formed by, for example, a CVD method.

(5) Forming Wiring WR2

Subsequently, the wiring WR2 is formed in the second insulating layer IL2. Specifically, the forming the wiring WR2 includes (5-1) forming the wiring trench WRT, (5-2) forming a conductive film CF′, and (5-3) performing CMP.

(5-1) Forming the Wiring Trench WRT

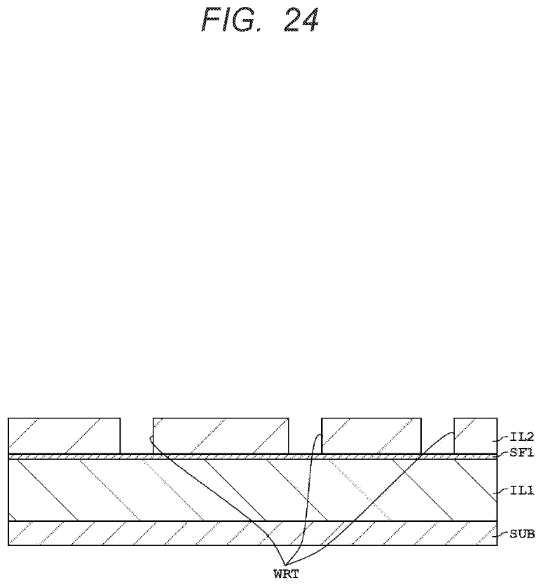

First, as shown in FIG. 24, the wiring trench WRT is formed in the second insulating layer IL2 so as to reach the first stopper film SF1 in the thickness direction of the second insulating layer IL2. A method of forming the wiring trench WRT is, for example, an etching method.

(5-2) Forming the Conductive Film CF′

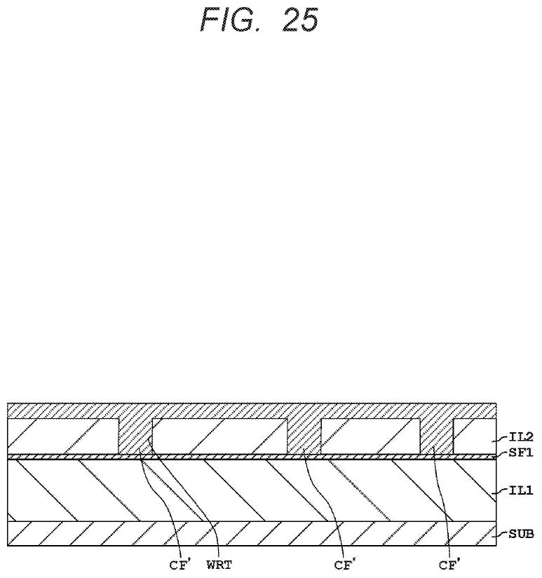

Subsequently, as shown in FIG. 25, the conductive film CF′ is formed on the second insulating layer IL2 to bury the wiring trench WRT. At this instance, the conductive film CF′ may also be formed on the second insulating layer IL2, or may not be formed on the second insulating layer IL2. A method of forming the conductive film CF′ is, for example, a plating method.

(5-3) Performing CMP

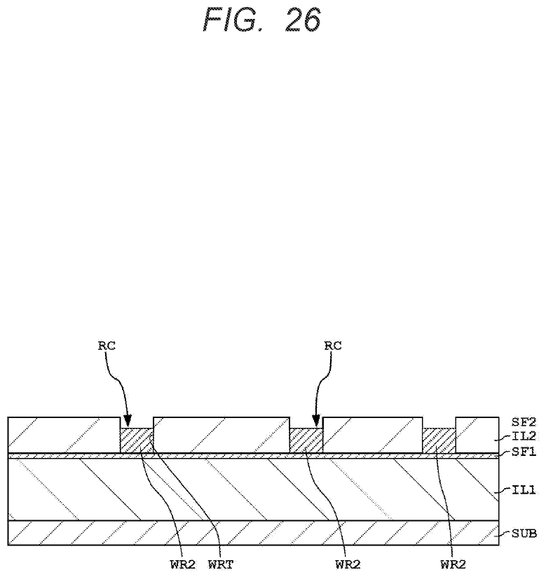

Subsequently, as shown in FIG. 26, among the conductive film CF′, a part formed outside the wiring trench WRT is removed. Thus, the wiring WR2 is formed in the wiring trench WRT. A method of removing the part of the conductive film CF′ is, for example, a CMP method. At this instance, in an interior of the wiring trench WRT, the recess RC is formed at the part (upper part) located above the wiring WR2. The recess RC is formed at the upper part of the wiring trench WRT.

(6) Forming the Second Conductive Film CF2

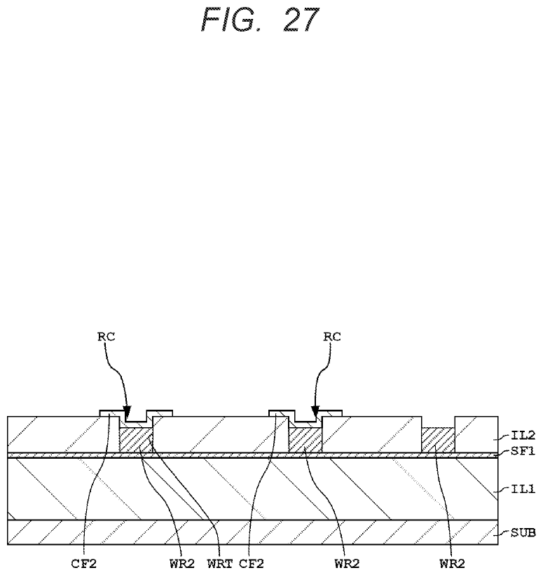

Subsequently, as shown in FIG. 27, the second conductive film CF2 is formed on at least the upper surface of the wiring WR2 and the inner surface of the wiring trench WRT. In the second embodiment, the second conductive film CF2 is formed on the upper surface of the wiring WR2, the inner surface of the wiring trench WRT, and the upper surface of the second insulating layer IL2. The second conductive film CF2 is formed by, for example, forming a conductive film by a sputtering method, and subsequently patterning the conductive film to a desired shape. A method of patterning the conductive film is, for example, an etching method.

(7) Forming the Thin-Film Resistor TFR and the Third Insulating Layer IL3

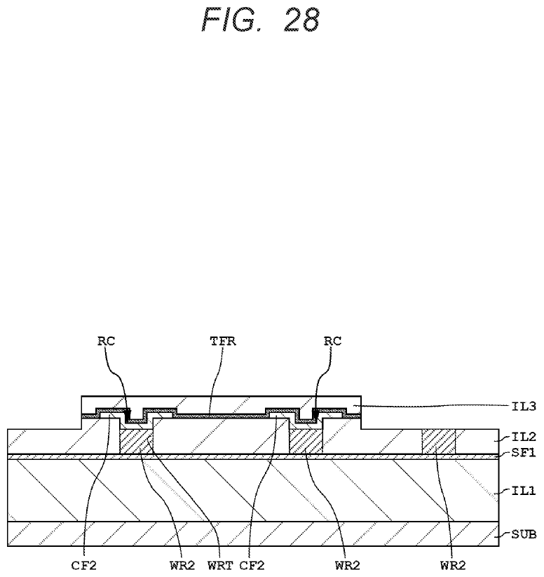

Subsequently, the thin-film resistor TFR and the third insulating layer IL3 are formed as shown in FIG. 28. The details are the same as those in the first embodiment.

(8) Forming the Second Stopper Film SF2

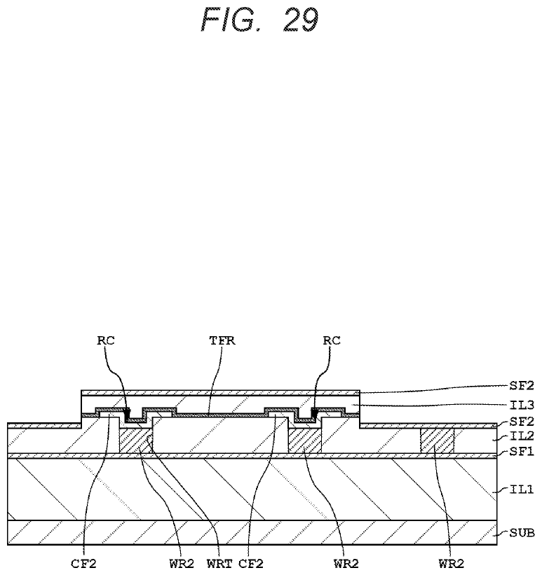

Subsequently, as shown in FIG. 29, the second stopper film SF2 is formed on the second insulating layer IL2 and the third insulating layer IL3. The second stopper film SF2 has a portion formed on the second insulating layer IL2, and a portion formed on the third insulating layer IL3. The second stopper film SF2 is formed by, for example, a sputtering method.

(9) Forming the Fourth Insulating Layer IL4

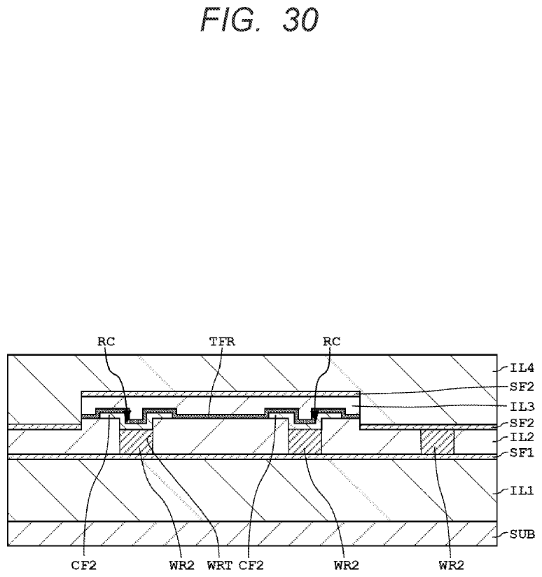

Subsequently, as shown in FIG. 30, the fourth insulating layer IL4 is formed on the second stopper layer SF2. The fourth insulating layer IL4 is formed by, for example, a CVD method.

(10) Forming Wiring WR3

Subsequently, the wiring WR3 is formed in the fourth insulating layer IL4. An exemplary method of forming the wiring WR3 is the same as the method of forming the wiring WR2.

The semiconductor device SD2 according to the second embodiment can be manufactured by the manufacturing method.

### Effect

The second embodiment has an effect similar to that of the first embodiment.

It should be noted that a present invention is not limited to the above embodiments, and various modifications can be made without departing from the gist thereof. The method of forming the recess RC may not be a CMP method. For example, the recessed RC may be formed by an etching method.

In addition, even when a specific numerical value example is described, it may be a numerical value exceeding the specific numerical value, or may be a numerical value less than the specific numerical value, except when it is theoretically obviously limited to the numerical value. In addition, with respect to the component, it is meant as “B containing A as a main component”, and the like, and does not exclude an embodiment containing other components. For the purpose of description of embodiments herein, terms such as “over,” “under,” “lower,” “upper,” “top,” “bottom,” and others are sometimes used in the context of the example orientations of different parts.

In addition, some of the embodiments and the modifications may be combined with each other.

What is claimed is:

1. A semiconductor device comprising:
an insulating layer having a penetrating portion;
a first conductive film formed in the penetrating portion such that a recess is formed at an upper part of the penetrating portion;
a second conductive film formed on an upper surface of the first conductive film and an inner surface of the penetrating portion; and
a thin-film resistor formed on the second conductive film and the insulating layer, the thin-film resistor comprising silicon and metal.

2. The semiconductor device according to claim 1,
wherein a size of an upper part of the recess is greater than a size of a lower part of the recess.

3. The semiconductor device according to claim 2,
wherein an inner surface of the recess is a curved surface.

4. The semiconductor device according to claim 1,
wherein a thickness of the second conductive film is smaller than a depth of the recess.

5. The semiconductor device according to claim 4,
wherein the depth of the recess is 4 or more times of a thickness of the thin-film resistor.

6. The semiconductor device according to claim 4,
wherein the depth of the recess is 10 or more times of a thickness of the thin-film resistor.

7. The semiconductor device according to claim 1,
wherein a thickness of the second conductive film is greater than a depth of the recess.

8. The semiconductor device according to claim 1,
wherein an end side surface of the second conductive film is inclined with respect to an upper surface of the insulating layer.

9. The semiconductor device according to claim 1,
wherein a material of the first conductive film comprises tungsten.

10. The semiconductor device according to claim 1,
wherein a material of the first conductive film comprises copper.

11. A method of manufacturing a semiconductor device, the method comprising:
forming a first conductive film in a penetrating portion formed in an insulating layer so as to form a recess at an upper part of the penetrating portion;
forming a second conductive film on an upper surface of the first conductive film and an inner surface of the penetrating portion; and,
forming a thin-film resistor on the second conductive film and the insulating layer.

12. The method according to claim 11, comprising performing isotropic etching on the recess.

13. The method according to claim 11, comprising performing isotropic etching on an outer edge part of the second conductive film.

14. The method according to claim 11,
wherein a thickness of the second conductive film is smaller than a depth of the recess.

15. The method according to claim 14,
wherein the depth of the recess is 4 or more times of a thickness of the thin-film resistor.

16. The method according to claim 14,
wherein the depth of the recess is 10 or more times of a thickness of the thin-film resistor.

17. The method according to claim 11,
wherein a thickness of the second conductive film is greater than a depth of the recess.
